(19) United States
(12) Patent Application Publication
(10) Pub. No.: US 2025/0393390 A1
(43) Pub. Date: Dec. 25, 2025

(54) ORGANIC LIGHT EMITTING ELEMENT AND MANUFACTURING METHOD THEREOF

(71) Applicant: TAIZHOU GUANYU TECHNOLOGY CO., LTD., ZHEJIANG PROVINCE (CN)

(72) Inventors: LI-CHEN WEI, TAICHUNG CITY (TW); KER TAI CHU, TAIPEI CITY (TW)

(21) Appl. No.: 19/241,440

(22) Filed: Jun. 18, 2025

(30) Foreign Application Priority Data
Jun. 24, 2024 (CN) 202410822385.3

(51) Int. Cl. H10K 50/16; H10K 50/17; H10K 71/16; H10K 102/00

(52) U.S. Cl. CPC H10K 50/167; H10K 50/171; H10K 71/16; H10K 2102/351

(57) ABSTRACT

An organic light emitting element and a manufacturing method thereof are provided. The organic light emitting element includes a substrate, a first electrode, an organic light emitting layer, a first inorganic barrier layer and a second electrode. The first electrode is over the substrate. The organic light emitting layer is the first electrode. The organic light emitting layer includes an electron injection layer and an electron transport layer. The electron injection layer includes an inorganic barrier material, and the electron transport layer includes an organic barrier material. The first inorganic barrier layer is between the first electrode and the organic light emitting layer. The second electrode is over the organic light emitting layer. The electron injection layer is between the electron transport layer and the second electrode.

### FIELD OF THE PRESENT DISCLOSURE

The present disclosure relates to an organic light emitting element and a manufacturing method thereof, and more particularly to an organic light emitting element including an organic light emitting diode (OLED) structure and a manufacturing method thereof.

### DESCRIPTION OF THE PRIOR ART

Currently, a fine metal mask (FMM) is commonly used in a coating step for a light emitting layer of an organic light emitting element, or white light in combination with a color film are used for a manufacturing process. However, fineness or resolution of pixels resulted from the manufacturing process above is rather poor.

### SUMMARY OF THE PRESENT DISCLOSURE

In the present disclosure, an organic light emitting element includes a substrate, a first electrode, an organic light emitting layer, a first inorganic barrier layer, and a second electrode. The first electrode is over the substrate. The organic light emitting layer is over the first electrode. The organic light emitting layer includes an electron injection layer and an electron transport layer. The electron injection layer includes an inorganic barrier material, and the electron transport layer includes an organic barrier material. The first inorganic barrier layer is between the first electrode and the organic light emitting layer. The second electrode is over the organic light emitting layer. The electron injection layer is between the electron transport layer and the second electrode.

In the present disclosure, a manufacturing method of an organic light emitting element includes: providing a substrate; disposing a first electrode over the substrate; forming a first inorganic barrier layer over the first electrode; forming a plurality of organic material layers over the first inorganic barrier layer; forming an electron transport layer over the plurality of organic material layers, which includes co-evaporating lithium quinolate and a phenanthroline compound on the plurality of organic material layers; and disposing a second electrode over the electron transport layer.

In some embodiments, the organic light emitting element further includes a plurality of organic material layers, the electron transport layer is in partial contact with the second electrode, and the plurality of organic material layers are spaced apart from the second electrode by the electron transport layer.

In some embodiments, the organic light emitting layer further includes an organic emission layer and a hole barrier layer. The hole barrier layer includes an organic barrier material and is between the organic emission layer and the electron transport layer.

In some embodiments, the hole barrier layer contacts the electron transport layer, and the organic emission layer is spaced apart from the second electrode by the hole barrier layer and the electron transport layer.

In some embodiments, the first inorganic barrier layer covers an upper surface and a side surface of the first electrode.

In some embodiments, the first inorganic barrier layer includes a transition metal oxide, and the organic barrier material includes a combination of lithium quinolate and a phenanthroline compound.

In some embodiments, the electron injection layer includes a lanthanide element.

In some embodiments, the organic light emitting element further includes a second inorganic barrier layer and a capping layer. The second inorganic barrier layer covers the second electrode. The capping layer is over the second inorganic barrier layer and is spaced apart from the second electrode by the second inorganic barrier layer.

In some embodiments, a thickness of the first inorganic barrier layer and a thickness of the second inorganic barrier layer are both equal to or less than 50 angstrom (A).

In some embodiments, a region in which the first electrode, the organic light emitting layer, and the second electrode overlap in a light emitting direction is defined as a light emitting region, and a ratio of an area of the light emitting region to a perimeter of an outline of the light emitting region is equal to or greater than 325.

In some embodiments, the manufacturing method of an organic light emitting element further includes: forming a hole barrier layer over the plurality of organic material layers before forming the electron transport layer, wherein the electron transport layer is formed over the hole barrier layer.

In some embodiments, forming the first inorganic barrier layer includes: depositing or coating a transition metal oxide on the first electrode.

In some embodiments, the manufacturing method of an organic light emitting element further includes: forming an electron injection layer over the electron transport layer, including depositing a lanthanide element on the electron transport layer.

In some embodiments, the manufacturing method of an organic light emitting element further includes: forming a second inorganic barrier layer covering the second electrode; and forming a capping layer over the second inorganic barrier layer, wherein the capping layer is spaced apart from the second electrode by the second inorganic barrier layer.

In some embodiments, forming the second inorganic barrier layer includes: depositing or coating a transition metal oxide on the second electrode.

### BRIEF DESCRIPTION OF THE DRAWINGS

FIG. 1 is a top view of an exemplary intermediate product of an organic light emitting element.

FIG. 2A is a cross-sectional diagram taken along the line A-A′ in FIG. 1 according to some embodiments.

FIG. 2B is a cross-sectional diagram taken along the line A-A′ in FIG. 1 according to some embodiments.

FIG. 2C is a cross-sectional diagram taken along the line A-A′ in FIG. 1 according to some embodiments.

FIG. 2D is a cross-sectional diagram taken along the line A-A′ in FIG. 1 according to some embodiments.

FIG. 2E is a cross-sectional diagram taken along the line A-A′ in FIG. 1 according to some embodiments.

FIG. 3 is a top view of a portion of an organic light emitting element according to some embodiments.

FIG. 4A to FIG. 4G depict a manufacturing method of an organic light emitting element according to some embodiments.

FIG. 5 is a relationship diagram of a ratio of the area of a light emitting region of an organic light emitting element to a perimeter of an outline of the light emitting region and a normalized light emitting intensity of the organic light emitting element according to some embodiments.

### DETAILED DESCRIPTION OF THE EMBODIMENTS

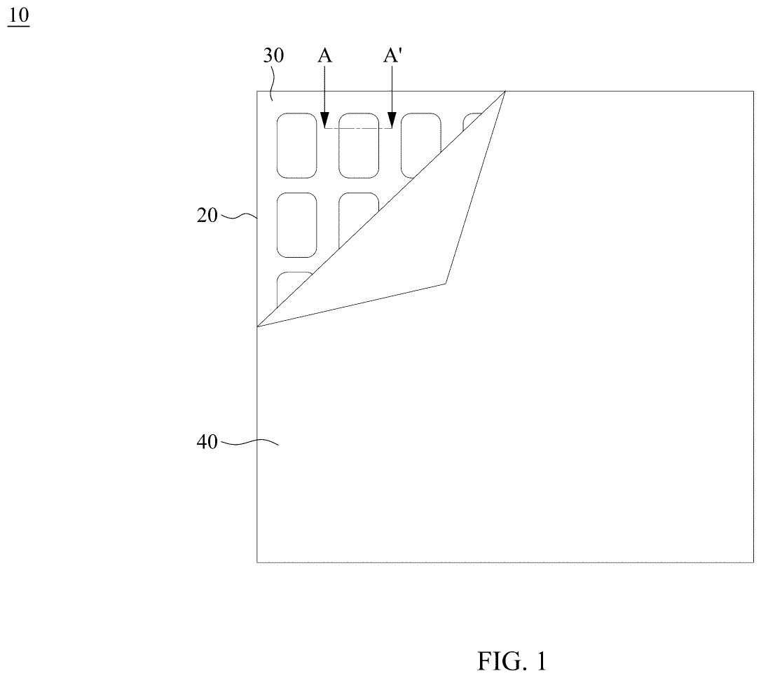

FIG. 1 shows a top view of an exemplary intermediate product of an organic light emitting element 10. The organic light emitting element 10 includes a light emitting layer 20 and a capping layer 40 over the light emitting layer 20. For the light emitting layer 20, a spacer structure 30 may be designed to provide a recess array used to accommodate a light emitting pixel array. In some embodiments, the spacer structure 30 may include a protrusion 310. In some embodiments, the spacer structure 30 may include a photosensitive material.

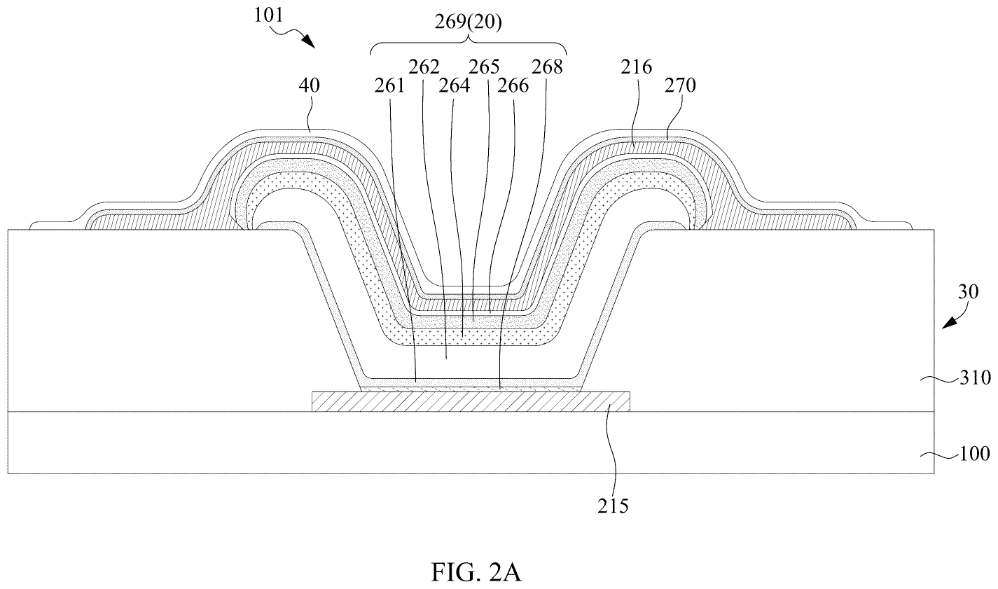

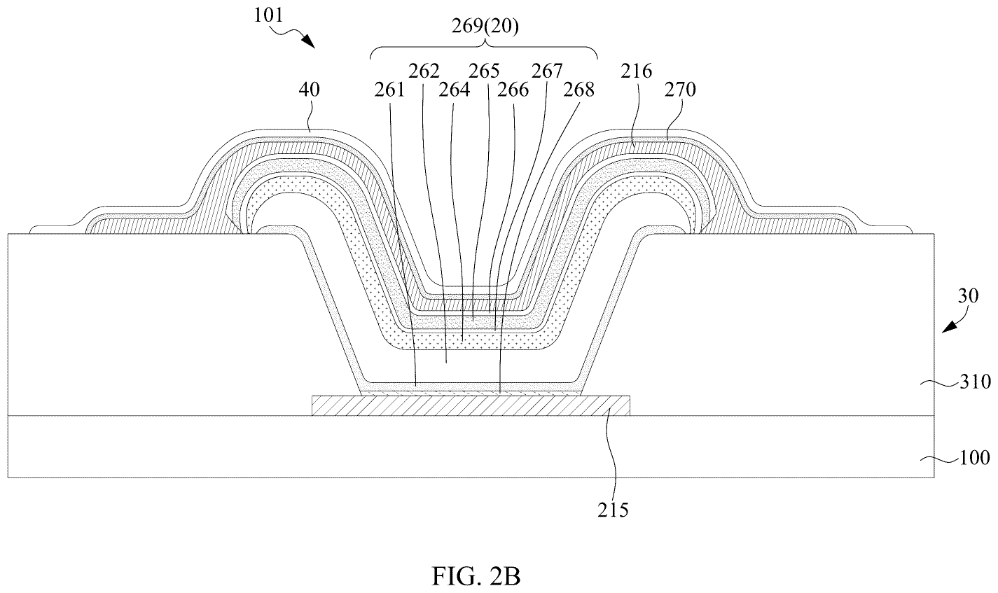

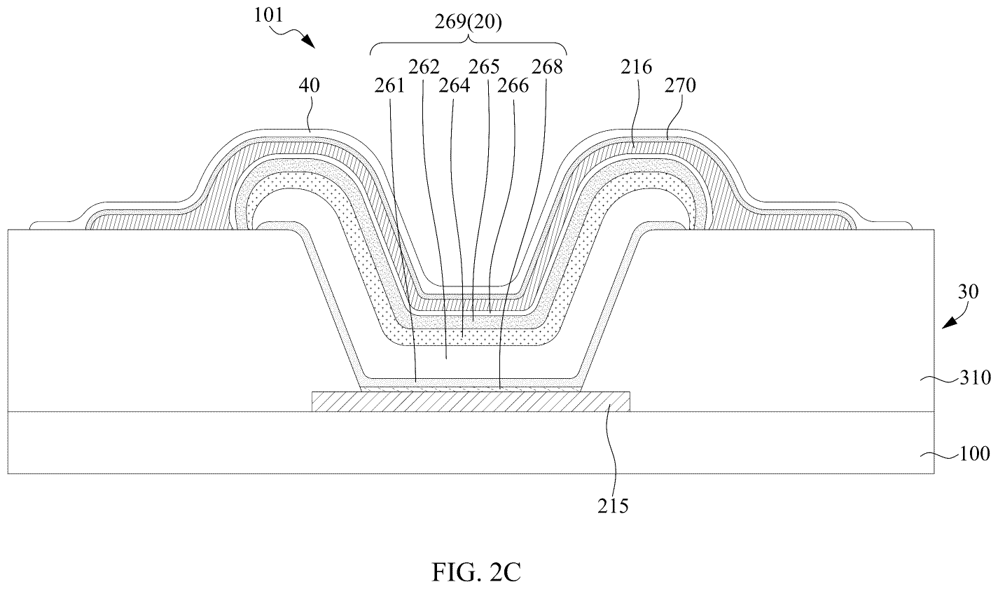

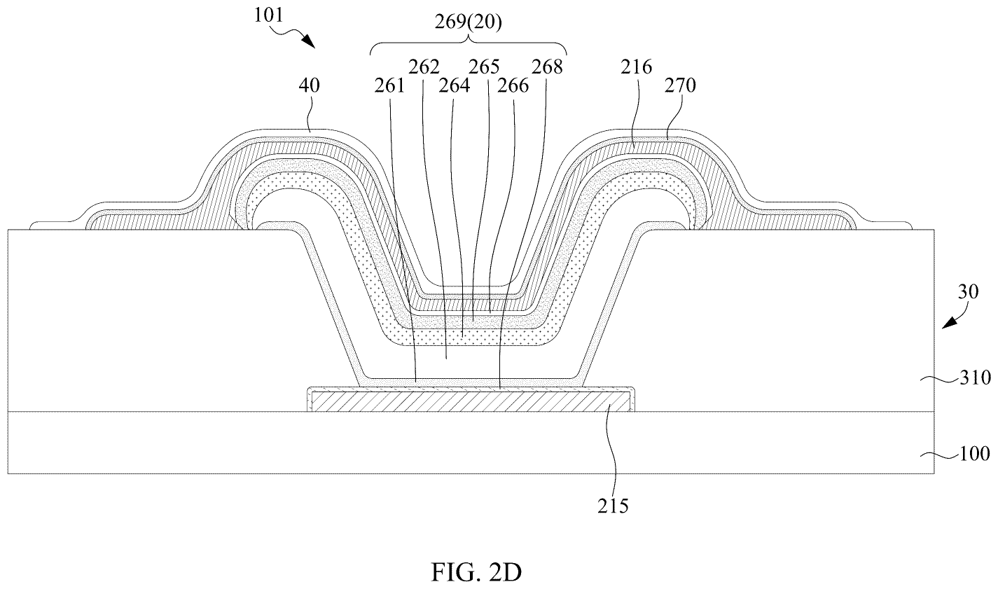

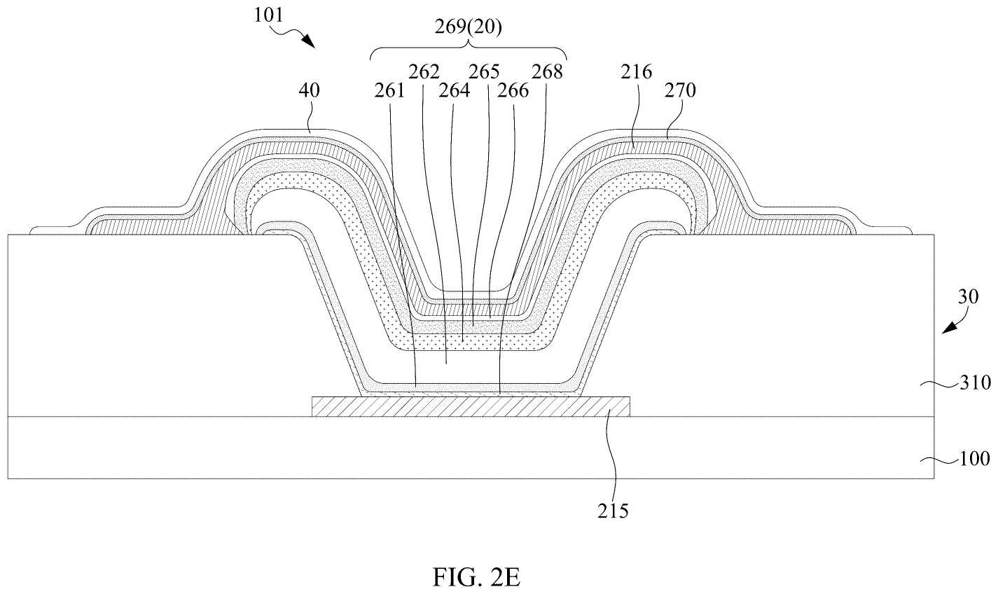

FIG. 2A shows a cross-sectional diagram taken along the line A-A′ in FIG. 1 according to some embodiments. In some embodiments, FIG. 2A shows a cross-sectional diagram taken along the line A-A′ in FIG. 1 as an example, and only a light emitting region is illustrated. The spacer structure 30 includes a plurality of protrusions 310 to define a light emitting pixel pattern. The recess is between two adjacent protrusions 310 and provides a space for accommodating light emitting pixels. When viewing the cross-sectional diagram shown in FIG. 2A, a person skilled in the art would be able to understand that the protrusions 310 are depicted in a disconnected manner. However, when viewing the schematic top view of FIG. 1, the protrusions 310 can be connected to one another by other parts of the spacer structure 30.

As shown in FIG. 2A, in some embodiments, the organic light emitting element 10 is, for example, a light emitting element including an organic light emitting diode (OLED) structure. In some embodiments, the organic light emitting element 10 may include a plurality of organic light emitting units (or referred to as light emitting pixels), for example, including at least a plurality of organic light emitting units 101. In some embodiments, the plurality of organic light emitting units 101 are between the protrusions 310 and over a substrate 100. The light emitting layer 20 may include an organic light emitting layer 269 corresponding to each of the organic light emitting units 101.

In some embodiments, the organic light emitting element 10 includes the substrate 100, an electrode 215 (or referred to as a first electrode), an electrode 216 (or referred to as a second electrode), the organic light emitting layer 269 (or the light emitting layer 20), the protrusions 310 (or the spacer structure 30) and the capping layer 40.

In some embodiments, the substrate 100 may include a transistor array, which is configured to correspond to light emitting pixels in the organic light emitting layer 269. The substrate 100 may include a plurality of capacitors. In some embodiments, two or more transistors are configured with one capacitor and one light emitting pixel to form a circuit. In some embodiments, the substrate 100 may include glass.

As shown in FIG. 2A, in some embodiments, the organic light emitting unit 101 includes the electrode 215 (or referred to as the first electrode), the organic light emitting layer 269, the electrode 216 (or referred to as the second electrode) and an inorganic barrier layer 270 (or referred to as a second inorganic barrier layer).

In some embodiments, the electrode 215 is over the substrate 100. In some embodiments, the electrode 215 is an anode of the organic light emitting unit 101. In some embodiments, the electrode 215 includes a metal material, for example, Ag, Al, Mg, Au, In, Sn, AlCu alloy, AgMo alloy, or InSn alloy. In some embodiments, the electrode 215 includes In, Sn, indium tin oxide (ITO), indium zinc oxide (IZO) or other appropriate materials.

In some embodiments, the organic light emitting layer 269 is over the electrode 215. In some embodiments, the organic light emitting layer 269 includes a plurality of organic material layers. In some embodiments, the organic material layers of the organic light emitting layer 269 include an organic material. In some embodiments, the organic material has an absorption of greater than or equal to 50% for a specific wavelength. In some embodiments, the organic material has an absorption of greater than or equal to 60% for a specific wavelength. In some embodiments, the organic material has an absorption of greater than or equal to 70% for a specific wavelength. In some embodiments, the organic material has an absorption of greater than or equal to 80% for a specific wavelength. In some embodiments, the organic material has an absorption of greater than or equal to 90% for a specific wavelength. In some embodiments, the organic material has an absorption of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the organic light emitting layer 269 includes a plurality of organic material layers, for example, a hole injection layer (HIL) 261, a hole transport layer (HTL) 262, an organic emission layer (EML) 264, an electron transport layer (ETL) 265, an electron injection layer (EIL) 266, and an inorganic barrier layer 268 (or referred to as a first inorganic barrier layer). In some embodiments, the electrode 216 is over the organic light emitting layer 269.

In some embodiments, the electron transport layer 265 includes an organic electron transport material and an organic barrier material. The organic electron transport material may be different from the organic barrier material. The organic barrier material may include a combination of lithium quinolate (Liq) and a phenanthroline compound. In some embodiments, the phenanthroline compound includes 4,7-diphenyl-1,10-phenanthroline (Bphen), 2,9-bis(naphthalene-2-yl)4,7-diphenyl-1,10-phenanthroline (NBphen), 1,3-bis(9-phenyl-1,10-phenanthroline-2-yl)benzene), 1,4-bis(2-phenyl-1,10-phenanthroline-4-yl)benzene (p-bPPhenB) and/or 1,3-bis(2-phenyl-1,10-phenanthroline-4-yl)benzene (m-bPPhenB), or any combination of the above. In some embodiments, the electron transport layer 265 is in partial contact with the electrode 216. In some embodiments, the hole injection layer 261, the hole transport layer 262, and the organic emission layer 264 are spaced apart from the electrode 216 by the electron transport layer 265.

According to some embodiments of the present disclosure, the organic barrier material in the electron transport layer 265 may be used to block metal atoms in the electrode 216 from diffusing into the organic light emitting layers 269 (for example, the hole injection layer 261, the hole transport layer 262, and the organic emission layer 264) to avoid quenching, hence preventing degradation of light emitting efficiency and further enhancing light emitting luminance and improving a color rendering index (Ra) of an organic light emitting element.

In some embodiments, the electron injection layer 266 includes an electron injection material and an inorganic barrier material. The electron injection material may be different from the inorganic barrier material. In some embodiments, the electron injection layer 266 is between the electron transport layer 265 and the electrode 216. The electron injection layer 266 may include a lanthanide element. In some embodiments, the electron injection layer 266 includes ytterbium (Yb). In some embodiments, the electron injection layer 266 is or includes a Yb metal layer.

According to some embodiments of the present disclosure, the organic barrier material in the electron transport layer 265 may be used in combination with the inorganic barrier material in the electron injection layer 266. Thus, with the combination of different barrier characteristics of the organic barrier material and the inorganic barrier material that complement each other, metal atoms in the electrode 216 are further blocked from diffusing into the organic light emitting layers 269 (for example, the hole injection layer 261, the hole transport layer 262, and the organic emission layer 264) to avoid quenching, hence preventing degradation of light emitting efficiency and further enhancing light emitting luminance and improving a color rendering index (Ra) of an organic light emitting element.

In some embodiments, the inorganic barrier layer 268 (or referred to as the first inorganic barrier layer) is between the electrode 215 and the organic light emitting layer 269. In some embodiments, a side surface of the inorganic barrier layer 268 contacts the protrusion 310. In some embodiments, the inorganic barrier layer 268 substantially completely covers an interface between the electrode 215 and the organic light emitting layer 269. In some embodiments, the inorganic barrier layer 268 includes a transition metal oxide. In some embodiments, the inorganic barrier layer 268 includes molybdenum oxide (MoO₃). In some embodiments, a thickness of the inorganic barrier layer 268 is equal to or less than 50 Å. In some embodiments, a ratio of the thickness of the inorganic barrier layer 268 to the thickness of the electrode 215 is less than 0.1, 0.06 or 0.03.

According to some embodiments of the present disclosure, the inorganic barrier layer 268 may be used to block metal atoms in the electrode 215 from diffusing into the organic light emitting layers 269 (for example, the hole injection layer 261, the hole transport layer 262, and the organic emission layer 264) to avoid quenching, hence preventing degradation of light emitting efficiency and further enhancing light emitting luminance and improving a color rendering index (Ra) of an organic light emitting element. Moreover, according to some embodiments of the present disclosure, the inorganic barrier layer 268 has an extremely small thickness relative to the electrode 215, thus the size in thickness of the organic light emitting element is not significantly increased, and an undesirable increase in a light emitting path is likewise not resulted.

In some embodiments, the electrode 216 is over the organic light emitting layer 269. In some embodiments, the electrode 216 is in contact with the organic light emitting layer 269. In some embodiments, the electrode 216 is a common electrode of all light emitting pixels in the light emitting layer 20. In some embodiments, the electrode 216 includes a metal material, for example, Ag, Al, Mg, Au, In, Sn, AlCu alloy, AgMo alloy, or InSn alloy. In some embodiments, the electrode 216 includes Ag, AgMo alloy or other appropriate materials. In some embodiments, the electrode 216 is a common electrode of all organic light emitting units in the organic light emitting element 10.

In some embodiments, the inorganic barrier layer 270 (or referred to as the second inorganic barrier layer) covers the electrode 216. In some embodiments, the inorganic barrier layer 270 contacts the capping layer 40. In some embodiments, the inorganic barrier layer 270 substantially completely covers an interface between the electrode 216 and the capping layer 40. In some embodiments, the inorganic barrier layer 270 includes a transition metal oxide. In some embodiments, the inorganic barrier layer 270 includes molybdenum oxide (MoO₃). In some embodiments, a thickness of the inorganic barrier layer 270 is equal to or less than 50 Å. In some embodiments, a ratio of the thickness of the inorganic barrier layer 270 to the thickness of the electrode 216 is less than 0.15, 0.1 or 0.05. In some embodiments, a ratio of the thickness of the inorganic barrier layer 270 to the thickness of the capping layer 40 is less than 0.5, 0.3 or 0.15.

According to some embodiments of the present disclosure, the inorganic barrier layer 270 may be used to block metal atoms in the electrode 216 from diffusing into an organic layer (for example, the capping layer 40), hence preventing degradation of light emitting efficiency and further enhancing light emitting luminance and improving a color rendering index (Ra) of an organic light emitting element. Moreover, according to some embodiments of the present disclosure, the inorganic barrier layer 270 has an extremely small thickness relative to the electrode 216 and the capping layer 40, thus the size in thickness of the organic light emitting element is not significantly increased, and an undesirable increase in a light emitting path is likewise not resulted.

In some embodiments, the spacer structure 30 is on the substrate 100 and partially covers the electrode 215. In some embodiments, the spacer structure 30 may be disposed among the plurality of organic light emitting layers 269. In some embodiments, the spacer structure 30 may include protrusions 310. In some embodiments, a pattern of the spacer structure 30 is designed according to a pixel layout. In some embodiments, the spacer structure 30 serves as a pixel defined layer (PDL). In some embodiments, the protrusions 310 define a pixel region. In some embodiments, each protrusion 310 fills a gap between two adjacent electrodes 215. Each electrode 215 is partially covered by the protrusion 310. In some embodiments, the spacer structure 30 includes an organic insulating material. In some embodiments, the spacer structure 30 includes a photosensitive material. In some embodiments, the spacer structure 30 may further include quantum dots, which have excellent light absorption performance. In some embodiments, the spacer structure 30 may further include a carbon black material, for example, carbon black nanoparticles, conductive fibers containing carbon black, or the like. In some embodiments, the spacer structure 30 may further include a black body material, which has an absorption of more than 90%, 95%, 99%, 99.5% or 99.9% for visible light.

In some embodiments, the spacer structure 30 has an absorption of greater than or equal to 50% for a specific wavelength. In some embodiments, the spacer structure 30 has an absorption of greater than or equal to 60% for a specific wavelength. In some embodiments, the spacer structure 30 has an absorption of greater than or equal to 70% for a specific wavelength. In some embodiments, the spacer structure 30 has an absorption of greater than or equal to 80% for a specific wavelength. In some embodiments, the spacer structure 30 has an absorption of greater than or equal to 90% for a specific wavelength. In some embodiments, the spacer structure 30 has an absorption of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the capping layer 40 is disposed over the electrode 216, and is substantially conformal with a non-flat upper surface of the electrode 216. The capping layer 40 may include a dielectric material or an inorganic insulating material, for example, SiO₂. In some embodiments, the capping layer 40 is over the inorganic barrier layer 270, and is spaced apart from the electrode 216 by the inorganic barrier layer 270.

According to some embodiments of the present disclosure, the organic light emitting element 10 includes the inorganic barrier layers 268 and 270, the electron transport layer 265 includes an organic barrier material, and the electron injection layer 266 includes a lanthanide element. Thus, with the structure and combination above, metal atoms in the electrodes 215 and 216 can be prevented from diffusing into the organic light emitting layer 269 to avoid quenching, hence preventing degradation of light emitting efficiency and further enhancing light emitting luminance of an organic light emitting element.

Moreover, according to some embodiments of the present disclosure, the electron injection layer 266 includes Yb and the electron transport layer 265 includes an organic barrier material formed by combining lithium quinolate (Liq) and a phenanthroline compound (for example, p-bPPhenB). Thus, even if the electron transport layer 265 is only partially covered by the electron injection layer 266 and is in partial contact with the electrode 216, the outstanding barrier ability thereof is still capable of effectively blocking metal atoms in the electrode 216 from diffusing into the organic light emitting layer 269, thereby effectively improving light emitting luminance and a color rendering index (Ra) of an organic light emitting element.

FIG. 2B shows a cross-sectional diagram taken along the line A-A′ in FIG. 1. In some embodiments, FIG. 2B shows a cross-sectional diagram taken along the line A-A′ in FIG. 1 as an example, and only a light emitting region is illustrated. The structure in FIG. 2B is similar to the structure in FIG. 2A, and differences therebetween are described below.

In some embodiments, the organic light emitting layer 269 further includes a hole barrier layer 267. In some embodiments, the hole barrier layer 267 includes a hole barrier material and an organic barrier material, and the hole barrier layer 267 is between the organic emission layer 264 and the electron transport layer 265. The hole barrier material may be different from the organic barrier material. In some embodiments, the hole barrier layer 267 is in partial contact with the electrode 216. In some embodiments, the hole barrier layer 267 contacts the electron transport layer 265, and the organic emission layer 264 is spaced apart from the electrode 216 by the hole barrier layer 267 and the electron transport layer 265.

In some embodiments, both of the electron transport layer 265 and the hole barrier layer 267 include an organic barrier material. In some embodiments, both of the electron transport layer 265 and the hole barrier layer 267 may include any combination of lithium quinolate (Liq) and a phenanthroline compound. In some embodiments, the phenanthroline compound includes 4,7-diphenyl-1,10-phenanthroline (Bphen), 2,9-bis(naphthalene-2-yl)4,7-diphenyl-1,10-phenanthroline (NBphen), 1,3-bis(9-phenyl-1,10-phenanthroline-2-yl)benzene), 1,4-bis(2-phenyl-1,10-phenanthroline-4-yl)benzene (p-bPPhenB) and/or 1,3-bis(2-phenyl-1,10-phenanthroline-4-yl)benzene (m-bPPhenB), or any combination of the above.

According to some embodiments of the present disclosure, the organic barrier material in the electron transport layer 265 may be used in combination with the organic barrier material in the hole barrier layer 267. Thus, with the combination of the organic barrier materials in the two layers that complement each other, metal atoms in the electrode 216 can be further blocked from diffusing into the organic light emitting layers 269 (for example, the hole injection layer 261, the hole transport layer 262 and the organic emission layer 264) to avoid quenching, hence preventing degradation of light emitting efficiency and further enhancing light emitting luminance and improving a color rendering index (Ra) of an organic light emitting element.

FIG. 2C shows a cross-sectional diagram taken along the line A-A′ in FIG. 1. In some embodiments, FIG. 2C shows a cross-sectional diagram taken along the line A-A′ in FIG. 1 as an example, and only a light emitting region is illustrated. The structure in FIG. 2C is similar to the structure in FIG. 2A, and differences therebetween are described below.

In some embodiments, the electron injection layer 266 substantially completely covers an interface between the electron injection layer 266 and the electron transport layer 265. In some embodiments, the electron injection layer 266 substantially completely covers the electron transport layer 265.

According to some embodiments of the present disclosure, the electron injection layer 266 substantially completely covers the electron transport layer 265, the electron injection layer 266 includes Yb, and the electron transport layer 265 includes an organic barrier material formed by combining lithium quinolate (Liq) and a phenanthroline compound (for example, p-bPPhenB). Thus, with the combination of the different barrier characteristics of the organic barrier material in the electron transport layer 265 and the inorganic barrier material (Yb) in the electron injection layer 266 that complement each other, metal atoms in the electrode 216 during the process of diffusion are first partially blocked by the electron injection layer 266, and then the remaining part is blocked by the electron transport layer 265. Hence, the configuration of the electron injection layer 266 substantially completely covering the electron transport layer 265 can further effectively block metal atoms in the electrode 216 from diffusing into the organic light emitting layers 269 (for example, the hole injection layer 261, the hole transport layer 262, and the organic emission layer 264) to avoid quenching, hence preventing degradation of light emitting efficiency and further enhancing light emitting luminance and improving a color rendering index (Ra) of an organic light emitting element.

FIG. 2D shows a cross-sectional diagram taken along the line A-A′ in FIG. 1. In some embodiments, FIG. 2D shows a cross-sectional diagram taken along the line A-A′ in FIG. 1 as an example, and only a light emitting region is illustrated. The structure in FIG. 2D is similar to the structure in FIG. 2A, and differences therebetween are described below.

In some embodiments, the inorganic barrier layer 268 covers an upper surface and a side surface of the electrode 216. In some embodiments, the inorganic barrier layer 268 substantially completely covers an interface between the electrode 216 and the protrusion 310.

According to some embodiments of the present disclosure, the inorganic barrier layer 268 may be used to block metal atoms in the electrode 215 from diffusing into the organic material of the protrusion 310, and then from diffusing through the organic material of the protrusion 310 to the organic light emitting layers 269 (for example, the hole injection layer 261, the hole transport layer 262, and the organic emission layer 264). Thus, the protrusion 310 in combination with the inorganic barrier layer 268 may serve as an auxiliary barrier layer to more effectively avoid quenching, hence preventing degradation of light emitting efficiency and further enhancing light emitting luminance and improving a color rendering index (Ra) of an organic light emitting element.

FIG. 2E shows a cross-sectional diagram taken along the line A-A′ in FIG. 1. In some embodiments, FIG. 2E shows a cross-sectional diagram taken along the line A-A′ in FIG. 1 as an example, and only a light emitting region is illustrated. The structure in FIG. 2E is similar to the structure in FIG. 2A, and differences therebetween are described below.

In some embodiments, the inorganic barrier layer 268 substantially completely covers an interface between the electrode 216 and the organic light emitting layer 269. In some embodiments, the inorganic barrier layer 268 further substantially completely covers an interface between the organic light emitting layer 269 and the protrusion 310.

According to some embodiments of the present disclosure, the inorganic barrier layer 268 may be used to block metal atoms in the electrode 215 from diffusing into the organic material of the protrusion 310, and then from diffusing through the organic material of the protrusion 310 to the organic light emitting layers 269 (for example, the hole injection layer 261, the hole transport layer 262, and the organic emission layer 264). Thus, the protrusion 310 in combination with the inorganic barrier layer 268 may serve as an auxiliary barrier layer to more effectively avoid quenching, hence preventing degradation of light emitting efficiency and further enhancing light emitting luminance and improving a color rendering index (Ra) of an organic light emitting element.

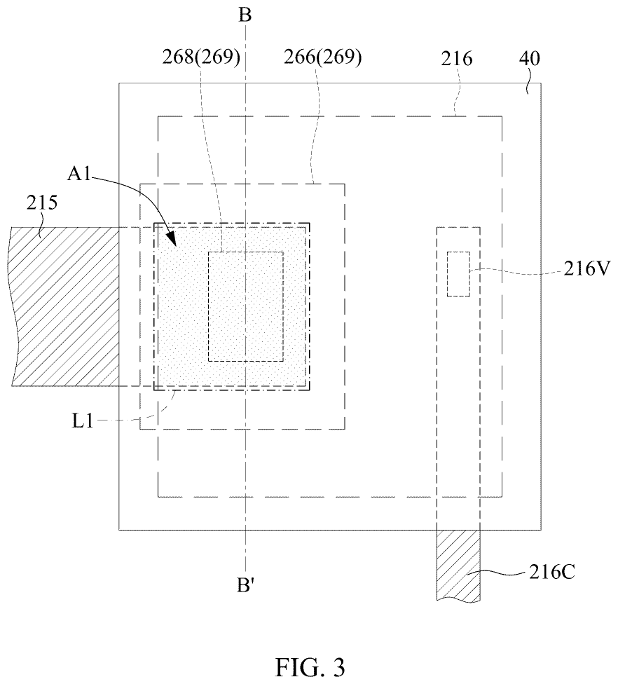

FIG. 3 shows a top view of a portion of an organic light emitting element according to some embodiments. In some embodiments, FIG. 2A, FIG. 2B, FIG. 2C, FIG. 2D or FIG. 2E may be a cross-sectional diagram taken along the line B-B′ in FIG. 3 according to some embodiments.

In some embodiments, the electrode 216 is connected to a conductive layer 216C via a conductive structure 216V (for example, a conductive via). In some embodiments, a region in which the electrode 215, the organic light emitting layer 269, and the electrode 216 overlap in a light emitting direction is defined as a light emitting region, and a ratio A1/L1 of an area A1 of the light emitting region to a perimeter L1 of an outline of the light emitting region is equal to or greater than 325. In some embodiments, the ratio A1/L1 of the area A1 of the light emitting region to the perimeter L1 of the outline of the light emitting region is equal to or greater than 500.

According to some embodiments of the present disclosure, when the ratio A1/L1 of the area A1 of the light emitting region to the perimeter L1 of the outline of the light emitting region is equal to or greater than 325, darkening from edges of the light emitting region can be effectively compensated to further improve light emitting luminance of an organic light emitting element.

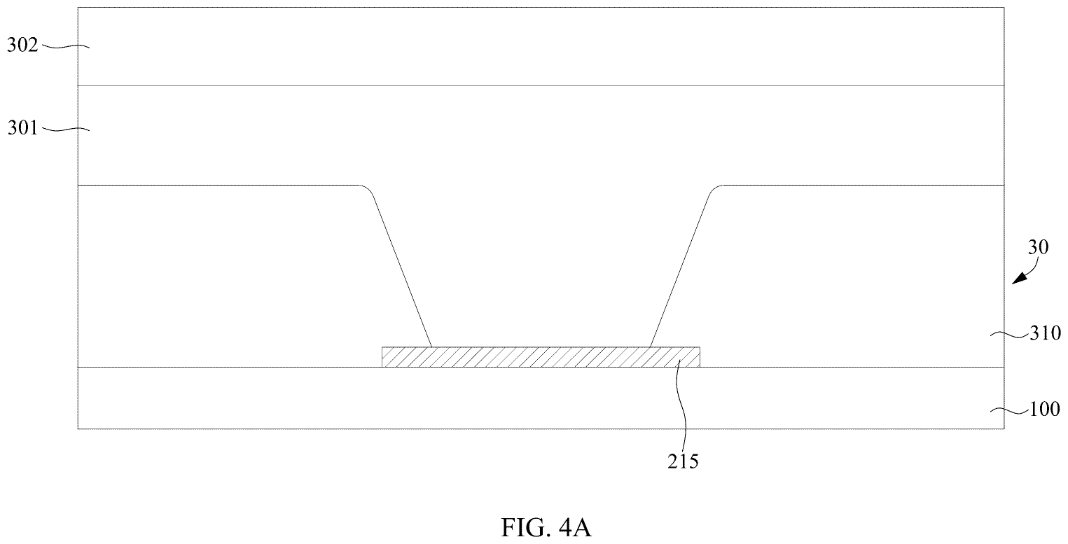

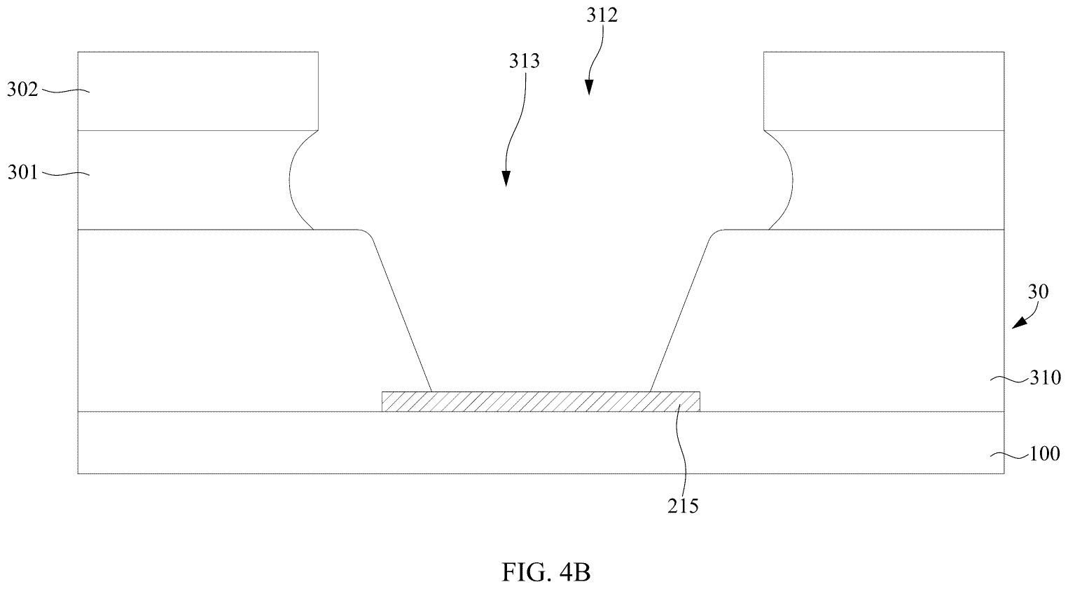

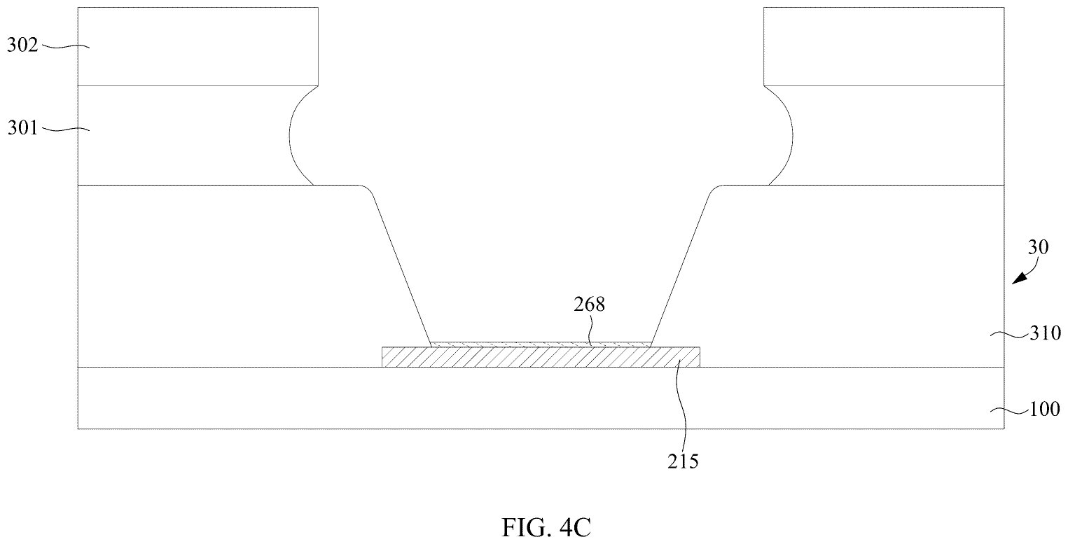

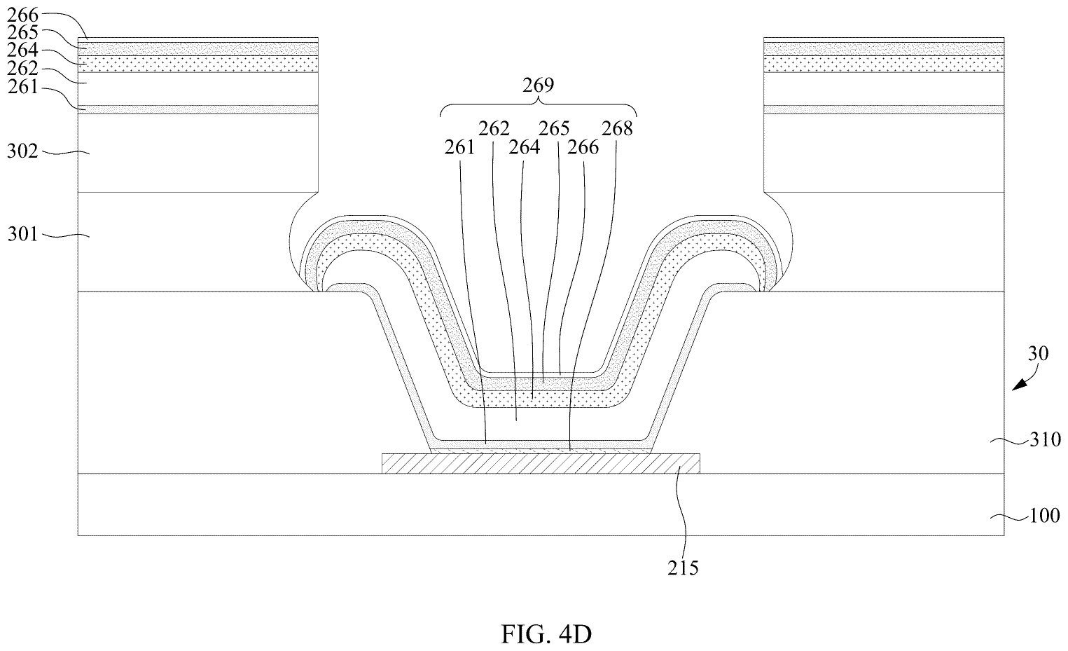

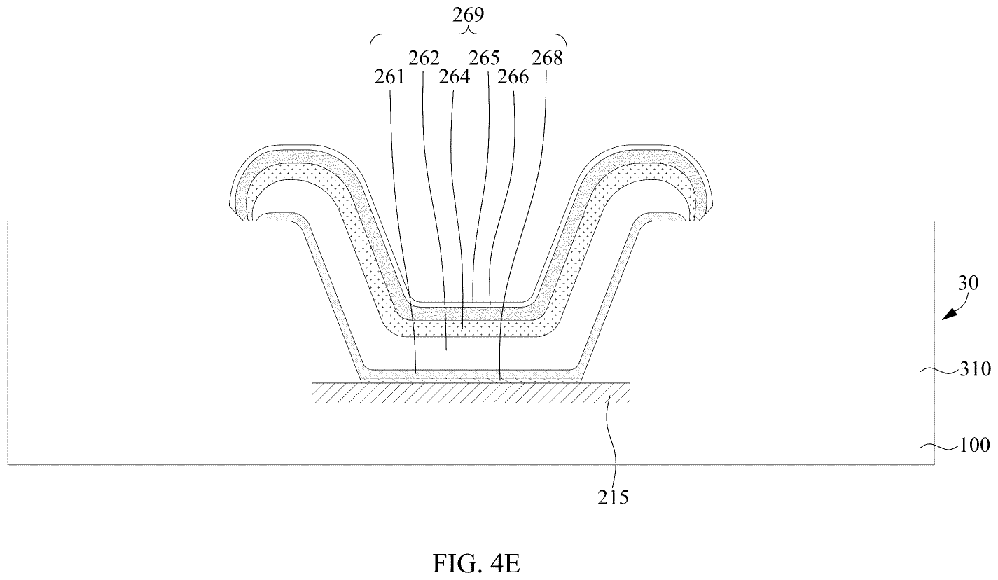

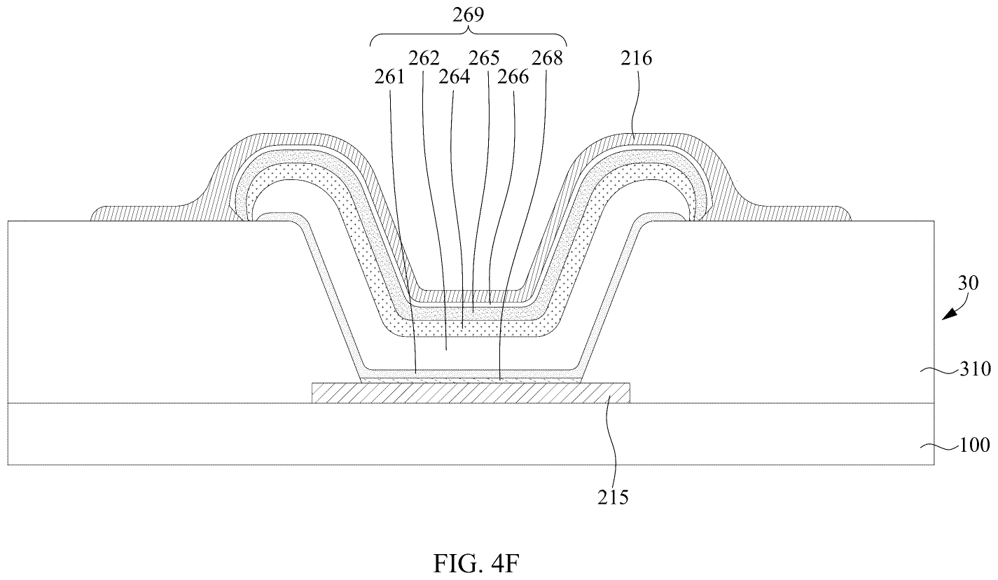

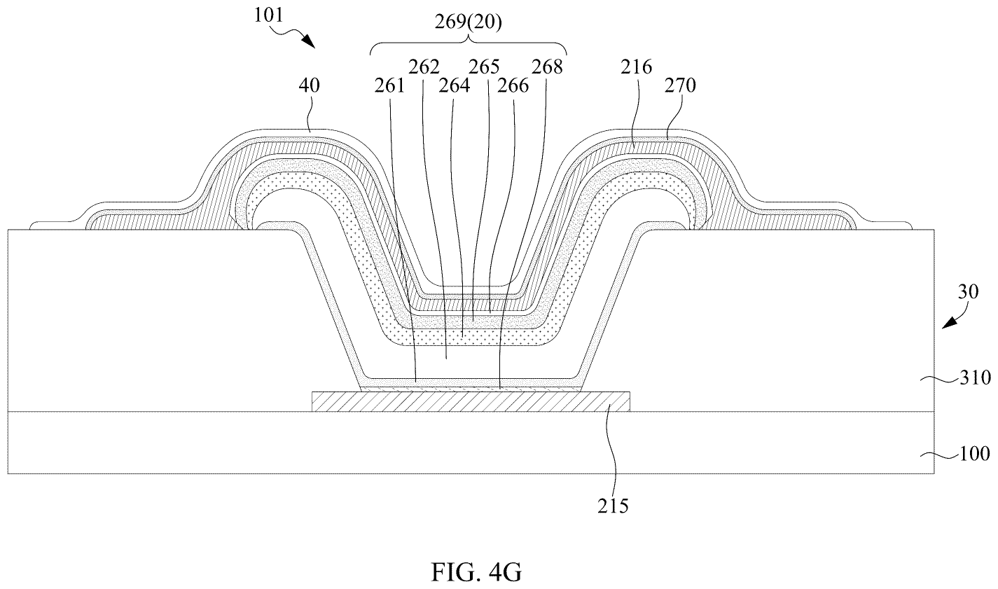

FIG. 4A to FIG. 4G depict a manufacturing method of an organic light emitting element 10 according to some embodiments.

As shown in FIG. 4A, in some embodiments, a substrate 100 is provided, an electrode 215 is disposed over the substrate 100, and a plurality of protrusions 310 (or a spacer structure 30) are formed, wherein each of the protrusions 310 fills a gap between the adjacent electrodes 215. Then, in some embodiments, a buffer layer 301 is disposed over the protrusions 310, wherein the buffer layer 301 also covers the electrode 215. The buffer layer 301 is used to block moisture from passing through or entering the protrusions 310. Next, in some embodiments, a photosensitive layer 302 is disposed over the buffer layer 301. In some embodiments, the buffer layer 301 and the photosensitive layer 302 are formed by coating.

As shown in FIG. 4B, in some embodiments, the photosensitive layer 302 is patterned by a lithography process, such that a portion of the buffer layer 301 is exposed through a trench 312. Next, in some embodiments, a portion of the buffer layer 301 is removed to form a trench 313. In some embodiments, the buffer layer 301 is removed by a wet etching process.

As shown in FIG. 4C, in some embodiments, an inorganic barrier layer 268 is formed over the electrode 215. In some embodiments, a transition metal oxide is coated on an upper surface of the electrode 215 to form the inorganic barrier layer 268. In some embodiments, since the inorganic barrier layer 268 is formed by plating, the inorganic barrier layer 268 is substantially formed only on the upper surface of the electrode 215.

As shown in FIG. 4D, in some embodiments, a plurality of organic material layers are formed over the inorganic barrier layer 268. In some embodiments, a hole injection layer 261 is disposed over the inorganic barrier layer 268, a hole transport layer 262 is disposed over the hole injection layer 261, and an organic emission layer 264 is disposed over the hole transport layer 262. Next, an electron transport layer 265 is disposed over the plurality of organic material layers (for example, the organic emission layer 264), and then an electron injection layer 266 is disposed over the electron transport layer 265. In some embodiments, the hole injection layer 261, the hole transport layer 262, the organic emission layer 264, the electron transport layer 265, and the electron injection layer 266 are formed by evaporation deposition.

In some embodiments, lithium quinolate and a phenanthroline compound are co-evaporated on the plurality of organic material layers (for example, the organic emission layer 264) to form the electron transport layer 265.

In some embodiments, a lanthanide element is deposited on the electron transport layer 265 to form the electron injection layer 266.

As shown in FIG. 4E, in some embodiments, the buffer layer 301, the photosensitive layer 302, and portions of the hole injection layer 261, the hole transport layer 262, the organic emission layer 264, the electron transport layer 265 and the electron injection layer 266 over the photosensitive layer 302 are removed. In some embodiments, the buffer layer 301, the photosensitive layer 302, a portion of the hole injection layer 261, a portion of the hole transport layer 262, a portion of the organic emission layer 264, a portion of the electron transport layer 265, and a portion of the electron injection layer 266 are removed by one or more wet etching processes.

As shown in FIG. 4F, in some embodiments, an electrode 216 (or a second electrode) is disposed over the organic light emitting layers 269 and the spacer structure 30. Up to this point, the organic light emitting unit 101 is formed.

As shown in FIG. 4G, in some embodiments, an inorganic barrier layer 270 is disposed over the electrode 216, and then a capping layer 40 is disposed over the inorganic barrier layer 270. In some embodiments, the inorganic barrier layer 270 covers the electrode 216. In some embodiments, the capping layer 40 is spaced apart from the electrode 216 by the inorganic barrier layer 270. In some embodiments, a transition metal oxide is deposited or coated on the electrode 216 to form the inorganic barrier layer 270. In some embodiments, the capping layer 40 is formed by evaporation deposition. Up to this point, the organic light emitting element 10 shown in FIG. 1 and FIG. 2A is formed.

According to some embodiments, referring to FIG. 4D and FIG. 2B, the hole barrier layer 267 may be formed over the above-mentioned plurality of organic material layers (for example, the organic emission layer 264) before forming the electron transport layer 265, and then the electron transport layer 265 is formed over the hole barrier layer 267. Next, in some embodiments, referring to FIG. 4D to FIG. 4G and FIG. 2B, the electrode 216 (or the second electrode) is disposed over the organic light emitting layers 269 and the spacer structure 30, and the organic light emitting element shown in FIG. 1 and FIG. 2B is formed up to this point.

According to some embodiments, referring to FIG. 4A and FIG. 2D, before forming the spacer structure 30, the inorganic barrier layer 268 may be formed over the electrode 215 (or the first electrode) to at least partially cover the upper surface and the side surface of the electrode 215. In some embodiments, a transition metal oxide is deposited on the upper surface and the side surface of the electrode 215 to form the inorganic barrier layer 268. Next, referring to FIG. 4B to FIG. 4G and FIG. 2D, the organic light emitting layer 269 and the spacer structure 30 are disposed over the electrode 215, the electrode 216 (or the second electrode) is disposed over the organic light emitting layer 269 and the spacer structure 30, and the organic light emitting element in shown FIG. 1 and FIG. 2D is formed up to this point.

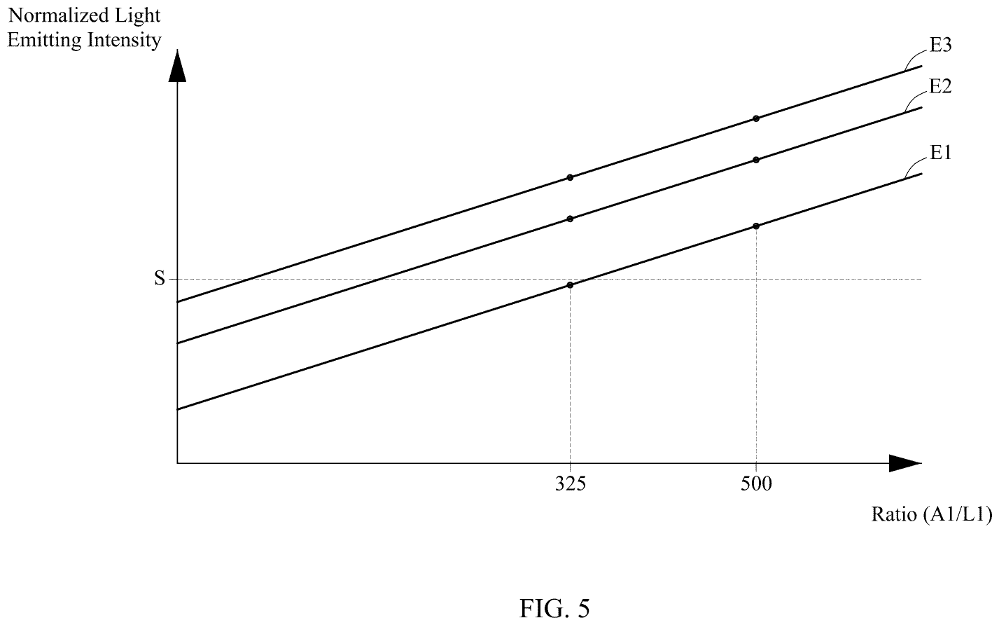

FIG. 5 shows a relationship diagram of the ratio A1/L1 of the area A1 of the light emitting region of the organic light emitting element to the perimeter L1 of the outline of the light emitting region and a normalized light emitting intensity of the organic light emitting element according to some embodiments.

In an embodiment E1 having a structure similar to that shown in FIG. 2A, the inorganic barrier layers 268 and 270 are not included, the electron transport layer 265 does not include any organic barrier material, and the electron injection layer 266 does not include any lanthanide element.

In an embodiment E2 having a structure as shown in FIG. 2A, both of the inorganic barrier layers 268 and 270 thereof include MoO₃, the electron transport layer 265 includes an organic barrier material, and the electron injection layer 266 includes a lanthanide element.

In an embodiment E3 having a structure as shown in FIG. 2B, both of the inorganic barrier layers 268 and 270 thereof include MoO₃, both of the electron transport layer 265 and the hole barrier layer 267 include an organic barrier material, and the electron injection layer 266 includes a lanthanide element.

As shown in FIG. 5, in the structure of the embodiment E1, when the ratio A1/L1 of the area A1 of the light emitting region to the perimeter L1 of the outline of the light emitting region is less than 325, the normalized light emitting intensity of the organic light emitting element is less than a pass line S (or referred to as a qualified standard line); when the ratio A1/L1 of the area A1 of the light emitting region to the perimeter L1 of the outline of the light emitting region is equal to or greater than 325, the normalized light emitting intensity of the organic light emitting element is greater than the pass line S. According to the above results, when the light emitting element does not include the inorganic barrier layer or the organic barrier material, metal atoms in the electrode diffuse to the organic light emitting layer 269, such that electrons and holes are unable to effectively recombine to emit light, leading to quenching and hence causing darkening of the light emitting region and reduced light emitting luminance of an organic light emitting element. However, according to some embodiments of the present disclosure, when the ratio A1/L1 of the area A1 of the light emitting region to the perimeter L1 of the outline of the light emitting region is equal to or greater than 325, darkening of the light emitting region can be effectively compensated so that the light emitting luminance of the organic light emitting element is still able to meet the expected pass line S.

As shown in FIG. 5, in the structure of the embodiment E2, the organic light emitting element includes the inorganic barrier layers 268 and 270, the electron transport layer 265 includes an organic barrier material, and the electron injection layer 266 includes a lanthanide element. Thus, metal atoms in the electrode can be effectively prevented from diffusing from a light emitting region (for example, edges of the light emitting region) to the organic light emitting layer 269 to avoid quenching, thereby preventing darkening from edges of the light emitting region and further improving light emitting luminance of the organic light emitting element. Thus, as shown in FIG. 5, even when the ratio A1/L1 of the area A1 of the light emitting region to the perimeter L1 of the outline of the light emitting region is less than 325, the normalized light emitting intensity of the organic light emitting element can still be higher than the pass line S.

As shown in FIG. 5, in the structure of the embodiment E3, the organic light emitting element includes the inorganic barrier layers 268 and 270, the electron transport layer 265 includes an organic barrier material, and the electron injection layer 266 includes a lanthanide element. Moreover, the organic light emitting element further includes the hole barrier layer 267 including an organic barrier material. Thus, metal atoms in the electrode can be even better prevented from diffusing into the organic light emitting layer 269 from a light emitting region (for example, edges of the light emitting region) to avoid quenching, thereby preventing darkening from edges of the light emitting region and further improving light emitting luminance of the organic light emitting element. Thus, as shown in FIG. 5, even when the ratio A1/L1 of the area A1 of the light emitting region to the perimeter L1 of the outline of the light emitting region is less than 325, the normalized light emitting intensity of the organic light emitting element can still be higher than the pass line S.

The features of some embodiments are described in brief above for a person skilled in the art to better understand various aspects of the present disclosure. A person skilled in the art would be able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the present disclosure, and various changes, substitutions and replacements may be made to the embodiments by a person skilled in the art without departing from the spirit and scope of the present disclosure.

What is claimed is:

1. An organic light emitting element, comprising:
a substrate;
a first electrode over the substrate;
an organic light emitting layer over the first electrode, wherein the organic light emitting layer comprises an electron injection layer and an electron transport layer, the electron injection layer comprises an inorganic barrier material, and the electron transport layer comprises an organic barrier material;
a first inorganic barrier layer between the first electrode and the organic light emitting layer; and
a second electrode over the organic light emitting layer, wherein the electron injection layer is disposed between the electron transport layer and the second electrode.

2. The organic light emitting element according to claim 1, wherein the organic light emitting layer further comprises a plurality of organic material layers, the electron transport layer is in partial contact with the second electrode, and the plurality of organic material layers are spaced apart from the second electrode by the electron transport layer.

3. The organic light emitting element according to claim 1, wherein the organic light emitting layer further comprises an organic emission layer and a hole barrier layer, the hole barrier layer comprises the organic barrier material and is disposed between the organic emission layer and the electron transport layer.

4. The organic light emitting element according to claim 3, wherein the hole barrier layer contacts the electron transport layer, and the organic emission layer is spaced apart from the second electrode by the hole barrier layer and the electron transport layer.

5. The organic light emitting element according to claim 1, wherein the first inorganic barrier layer covers an upper surface and a side surface of the first electrode.

6. The organic light emitting element according to claim 1, wherein the first inorganic barrier layer comprises a transition metal oxide, and the organic barrier material comprises a combination of lithium quinolate and a phenanthroline compound.

7. The organic light emitting element according to claim 1, wherein the electron injection layer comprises a lanthanide element.

8. The organic light emitting element according to claim 1, further comprising:
a second inorganic barrier layer covering the second electrode; and
a capping layer over the second inorganic barrier layer and spaced apart from the second electrode by the second inorganic barrier layer.

9. The organic light emitting element according to claim 8, wherein a thickness of the first inorganic barrier layer and a thickness of the second inorganic barrier layer are both equal to or less than 50 angstrom (A).

10. The organic light emitting element according to claim 1, wherein a region in which the first electrode, the organic light emitting layer, and the second electrode overlap in a light emitting direction is defined as a light emitting region, and a ratio of an area of the light emitting region to a perimeter of an outline of the light emitting region is equal to or greater than 325.

11. A manufacturing method of an organic light emitting element, comprising:
providing a substrate;
disposing a first electrode over the substrate;
forming a first inorganic barrier layer over the first electrode;
forming a plurality of organic material layers over the first inorganic barrier layer;
forming an electron transport layer over the plurality of organic material layers, comprising co-evaporating lithium quinolate and a phenanthroline compound on the plurality of organic material layers; and
disposing a second electrode over the electron transport layer.

12. The manufacturing method according to claim 11, further comprising:
forming a hole barrier layer over the plurality of organic material layers before forming the electron transport layer, wherein the electron transport layer is formed over the hole barrier layer.

13. The manufacturing method according to claim 11, wherein forming the first inorganic barrier layer comprises:
depositing or coating a transition metal oxide on the first electrode.

14. The manufacturing method according to claim 11, further comprising:
forming an electron injection layer over the electron transport layer, comprising depositing a lanthanide element on the electron transport layer.

15. The manufacturing method according to claim 11, further comprising:
forming a second inorganic barrier layer covering the second electrode; and
forming a capping layer over the second inorganic barrier layer, wherein the capping layer is spaced apart from the second electrode by the second inorganic barrier layer.

16. The manufacturing method according to claim 15, wherein forming the second inorganic barrier layer comprises:
depositing or coating a transition metal oxide on the second electrode.
